(19) United States
(12) Patent Application Publication
(10) Pub. No.: US 2015/0159898 A1
(43) Pub. Date: Jun. 11, 2015

(54) AIR CONDITIONING MANAGEMENT SYSTEM FOR DATA CENTER AND MANAGEMENT METHOD OF THE SAME

(71) Applicant: ELECTRONICS AND TELECOMMUNICATIONS RESEARCH INSTITUTE, Daejeon (KR)

(72) Inventor: Byung Kwon JUNG, Daejeon (KR)

(73) Assignee: ELECTRONICS AND TELECOMMUNICATIONS RESEARCH INSTITUTE, Daejeon (KR)

(21) Appl. No.: 14/244,270

(22) Filed: Apr. 3, 2014

(30) Foreign Application Priority Data
Dec. 10, 2013 (KR) 10-2013-0153004

(51) Int. Cl. F24F 11/00; G05D 23/19; H05K 7/20

(52) U.S. Cl. CPC F24F 11/0009; H05K 7/20736; H05K 7/20836; G05D 23/19

(57) ABSTRACT

An embodiment of the present invention relates to an air conditioning management apparatus which can increase the Power Usage Effect (PUE) by utilizing the sensing information inside and outside a data center, and includes a sensor for detecting a temperature of an air exhausted from server racks, detecting the degree of contamination of a filter for purifying an outside air, and outputting a sensing information for it; a power supply for supplying a operation power to a exhaust blower for exhausting an inside air of the data center to an outside and an air supply blower for supplying the outside air to the data center; and a controller for controlling operations of the exhaust blower and the air supply blower by controlling the power supply depending on the sensing information, and determining and notifying a replacement time of the filter.

### BACKGROUND OF THE INVENTION

1. Field of the Invention

The present invention relates to an apparatus and method for managing air conditioning of a data center, more specifically, an air conditioning management apparatus and management method of the same for increasing the Power Usage Effect (PUE) by utilizing the sensing information inside and outside a data center.

2. Background of the Invention

Until recently, it was not many interested in energy cost which is used to IT systems. However, depending on the increase of electricity prices and power consumption, energy costs is becoming one of important factors when making decisions about the design and data center position.

As a result of the analysis of energy usage in the data center, it is analyzed that IT system occupies 50% of the total data center electricity consumption. It shows that a system next to the electricity consumption of IT systems is a cooling system, which occupies 37% of total electricity consumption of data center.

Depending on the recent explosive usage amount of computer, the size of the data center has been enlarged. Now, although it is depending on the size of the data center, the electricity consumption amount of domestic and overseas data center is equivalent to the energy consumption used in small and medium-sized cities. Accordingly, when designing a data center from 2000, by the design of efficient server room cooling and air conditioning management, data center design of low power consumption concept is being carried out.

In order to optimize the cooling environment of the data center to remove the heat as much as possible from the device with the minimum energy, to ensure efficient ventilation routes is important. In order to optimize ventilation routes (flow of air) in the data center, rack configuration and air conditioning management system placement must be optimized. Today, in most data centers, the rack is placed so that the cooled wind flow from the front of the rack and the hot air is exhausted back. Speaking once again, the hot air region (Hot zone) and cold air region (Cold zone) are formed on the peripheral side of the rack.

Therefore, after equipping with an air conditioning management facility so that hot air and hot air are not mixed each other, it is needed that hot air is exhausted outside the data center and cold outer air is flowed into the data center by an efficient and less energy.

### PRIOR ART

### [Patent Document] KR 10-1134468

### [Patent Document] KR 10-1308969

### BRIEF SUMMARY OF THE INVENTION

The present invention controls air conditioning of a data center, thereby maximizing energy efficiency (power efficiency) by controlling a blower and a filter using a sensor.

An air conditioning management apparatus of a data center according to an embodiment of the present invention includes a detector for detecting a temperature of an air exhausted from server racks, detecting the degree of contamination of a filter for purifying an outside air, and outputting a sensing information for it; a power supply for supplying a operation power to a exhaust blower for exhausting an inside air of the data center to an outside and an air supply blower for supplying the outside air to the data center; and a controller for controlling operations of the exhaust blower and the air supply blower by controlling the power supply depending on the sensing information, and determining and notifying a replacement time of the filter.

Preferably, rear parts of the server racks are arranged to face each other, spacing a distance apart, and forms a hot zone that causes a hot air emitted from the server racks to be collected in the rear part, the detector detects a temperature of the hot zone.

An air conditioning management method of the data center according to an embodiment of the present invention is an air conditioning management method of an air conditioning management apparatus of data center which rear parts of server racks are arranged to face each other, spacing a distance apart, and a hot zone that causes a hot air emitted from the server racks to be collected in the rear part is formed, the method comprising the steps of: detecting a temperature of the hot zone and the degree of contamination of a filter for purifying a outside air; exhausting the air of the hot zone to outside by operating an exhaust blower and supplying the outside air through the filter to the data center by operating an air supply blower; and outputting a message notifying a replacement of the filter, If the degree of contamination of the filter is more than a reference value or equal to the reference value.

### Effect of the Invention

The present invention can controls air conditioning of a data center while maximizing energy efficiency, by controlling exhaust and intake blowers using a sensor and automatically checking the replacement time of the filter for purifying outside air.

### BRIEF DESCRIPTION OF THE DRAWINGS

FIG. 1 is a diagram showing a rack placement and a installation view of a closed exhaust diffuser in the data center according to an embodiment of the present invention.

FIG. 2 is a configuration diagram showing the entire configuration of an air conditioning management system in the data center according to an embodiment of the present invention.

FIG. 3 is a diagram showing in more detail the constitution of the air conditioning management apparatus according to an embodiment of the present invention.

FIG. 4 is a flowchart illustrating a method for managing the exhaust operation in the air conditioning management method according to an embodiment of the present invention.

FIG. 5 is a flowchart illustrating a method for managing the replacement of an air supply filter in the air conditioning management method according to an embodiment of the present invention.

### DESCRIPTION OF EMBODIMENTS

Hereinafter, referring to drawings attached, preferred embodiments of the present invention will be described in detail. Prior to this, words and terms used in this specification and claims must not be construed as being limited in an usual or dictionary meaning, and must be understood as the meaning and concept meeting the technical concept of the present invention based on the principle that a inventor can properly defines the concept of term to explain the invention with the best way. Thus, since embodiments described herein and constitutions shown in drawings are just preferable embodiments and not represent all technical concept of the present invention, at the time of the filing of this application, it must be understood that there are various equivalents and modifications which can replace them.

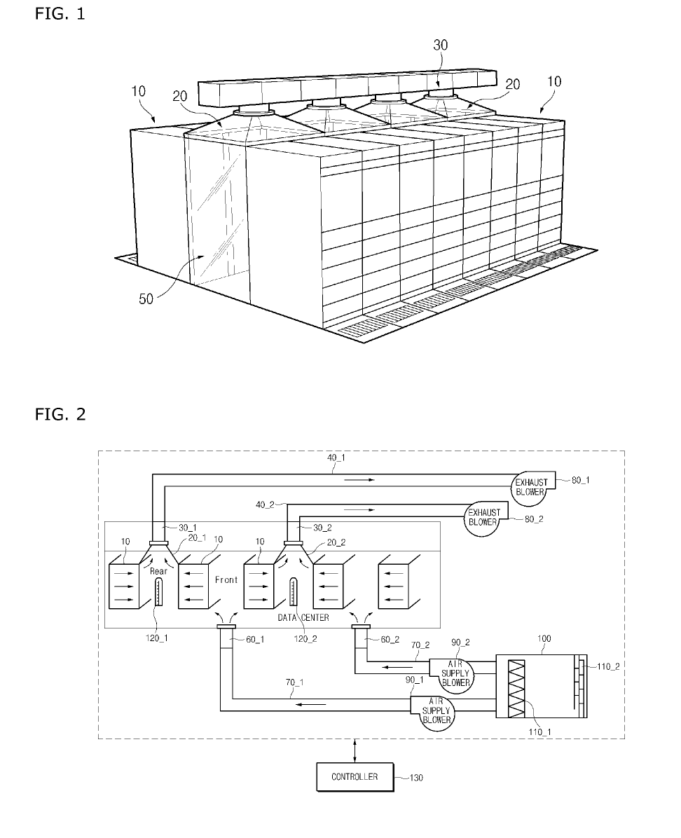

FIG. 1 is a diagram showing a rack placement and a installation view of a closed exhaust diffuser in the data center according to an embodiment of the present invention.

A plurality of Server racks (10), parts heat is generated, in other words, rear of the rack is spaced distance apart, are arranged in two rows so as to face each other, and an access door (50) is formed between the server racks of the outermost both of the arranged server racks (10). The access door (50) serve as dividing the rear space of server racks (10) into the space for confining hot air emitted from the server rack (10) (hereinafter, “Hot Zone”), and is also used as doorway for maintenance of the server.

On the top of hot zone, a pyramid diffuser (20), a exhaust diffuser (30) and a exhaust duct (40) are formed, and hot air confined in the hot zone is exhausted to the outside of the data center. The pyramid diffuser (20) and the access door (50) is able to be made of a transparent material so that the illumination of the data center can be transmitted to the hot zone. On the front floor of the rack server (10), an air flow panel (60) is installed. The outside air for cooling the inside of the data center is introduced into the data center through the air flow panel (60).

FIG. 2 is a configuration diagram showing the entire configuration of an air conditioning management system in the data center according to an embodiment of the present invention.

In the data center, there are a plurality of arrangement of the server racks (10) shown in FIG. 1, and on the top of each server rack arrangement, the pyramid diffuser (20_1, 20_2) the exhaust diffuser (30_1, 30_2) and the exhaust duct (40_1, 40_2) are installed. In other words, the hot air confined in each the hot zone is exhausted via the exhaust diffuser (30_1, 30_2) through the exhaust duct (40_1, 40_2) to the outside of the data center by pressure of an exhaust blower (80_1, 80_2).

In each hot zone, a temperature sensor (120_1, 120_2) to measure the temperature of the hot zone is installed. The temperature information for each hot zone measured from the temperature sensor (120_1, 120_2) is transmitted to a control device (130). The control device (130) control exhausting the hot air in the hot zone into the outside of the data center by controlling operating speed (blowing speed) of each exhaust blower (80_1, 80_2) according to the temperature information of each hot zone.

The air flow panel (Air flow Panel) (60) is connected to an air supply duct (70_1, 70_2) installed at the bottom of the data center. Each air supply duct (70_1, 70_2) is connected to an air supply blower (90_1, 90_2), the air supply blower (90_1, 90_2) is connect to a filter box (100). In other words, the outside air for cooling the inside of the data center is flowed through the filter box (100) by the pressure of the air supply blower (90_1, 90_2) and via air supply duct (70_1, 70_2), supplied to the inside of the data center.

The filter box (100) includes a filter (110_1) to purify the outside air and an infrared sensor (110_2) to detect the degree of contamination of the filter (110_1). At this time, the filter (110_1) includes a HEPA (HEPA: High Efficiency Particulate Air) filter. The infrared sensor (110_2) detects color index (degree of monochrome) of the filter (110_1). For example, if a lot of dust is stuck to the filter (110_1), the color of the filter (110_1) is changed to black color, and since the light projection ratio become low, the infrared sensor (110_2) can detects the degree of contamination by measuring the light projection ratio. The infrared sensor (110-2) transfers the detected results to the control device (130).

The controller (130) outputs the signal (message) to inform the operator of filter replacement as long as the contamination state of the filter (110_1) is more than the reference value. In this time, the control device (130) is able to determine the contamination level of the filter by using the average value after having received multiple times signals from infrared sensor (110_2).

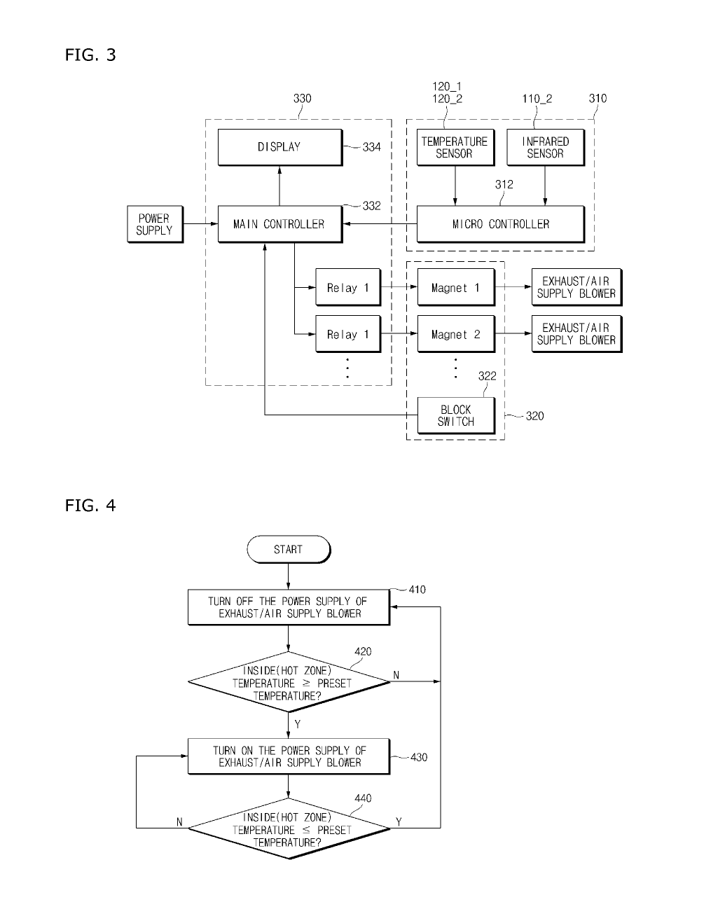

FIG. 3 is a diagram showing in more detail the constitution of the air conditioning management apparatus according to an embodiment of the present invention.

The air conditioning management apparatus includes a detector (310), a power supply (320) and a controller (330).

The detector (310) detects the temperature of the hot zone in the data center, detects degree of contamination of the filter (110_1) installed in the filter box (100), and then transfer the detected sensing information to the controller (330). This detector (310) may includes a temperature sensor (120_1, 120_2) installed on the hot zone in the data center, a infrared sensor (110_2) for detecting degree of contamination installed in the filter box (100), and a microcontroller (312) for processing the signal sensed from the temperature sensor (120_1, 120_2) and the infrared sensor (110_2) and transferring the sensing information to a main controller (332) of the controller (330).

A power supply (320) selectively supplies the operating power to the exhaust blower (80_1, 80_2) and air supply blower (90_1, 90_2) depending on the control signal from the controller (300). The power supply (320) is connected to the exhaust blower (80_1, 80_2) and air supply blower (90_1, 90_2), and includes magnets that are on or off depending on the control signal of the main controller (332) of the controller (330) and a block switch (322) that allows the user to manually block the power at the time of the malfunction of the magnet.

The controller (330) controls the operation of the exhaust blower (80_1, 80_2) and air supply blower (90_1, 90_2) by controlling the operation of the power supply (320) depend on the sensing information from the detector (310). That is, the main controller (332) of the controller (330) controls whether the operation power is supplied to the exhaust blower (80_1, 80_2) and air supply blower (90_1, 90_2) connected to magnets (Magnet 1, Magnet 2) or not, by selectively turning on/off the magnets (Magnet 1, Magnet 2) of the power supply (320). And, the main controller (332) may controls the blowing speed of the exhaust blower (80_1, 80_2) and the air supply blower (90_1, 90_2) by controlling the power amount supplied to the exhaust blower (80_1, 80_2) and the air supply blower (90_1, 90_2) through the magnets (Magnet 1, Magnet 2) when the magnets (Magnet 1, Magnet 2) is on state. At this time, the main controller (332) eliminates a noise generated at the time of the on/off operation of the magnets (Magnet 1, Magnet 2) using relays (Relay 1, Relay 2). Also, the main controller (332) determines the replacement necessity (replacement time) of the filter (110_1) in the filter box (100) depending on the sensing information from the microcontroller (312), and may display the message requesting the replacement of the filter on display unit (334) if it is determined that the replacement is needed. In addition, the main controller (332) generates the control signal turning off the magnets of the power supply (320) and transmits the signal to the power supply (320), if the blocking signal is received from the block switch (322) of the power supply (320).

FIG. 4 is a flowchart illustrating a method for managing the exhaust operation in the air conditioning management method according to an embodiment of the present invention.

The exhaust blower (81_1, 80_2) for exhausting the hot air of the hot zone maintains a state that the power supply is usually turned off (step 410).

At this time, the micro controller (312) periodically checks the temperature of each hot zone using the temperature sensor (120_1, 120_2) and transfers the sensing information from the temperature sensor (120_1, 120_2) to the main controller (332)

The main controller (332) compares the temperature of each hot zone with the preset reference temperature depending on the temperature information received from the micro controller (312) (step 420)

At this time, if the temperature of a specific hot zone is more than the reference temperature, main controller (332) supplies the operation power to the exhaust blower (for example, 80_1) and the air supply blower (for example, 90_1) corresponding to the hot zone which the temperature is high by turning on the corresponding magnet (for example, Magnet 1) (step 430).

According to the supply of the operation power, if the exhaust blower (80_1) and the air supply blower (90_1) operate, the hot air of the corresponding hot zone is exhausted via the exhaust diffuser (30_1) through the exhaust duct (40_1) to the outside of the data center. And, by the pressure of the air supply blower (90_1), the outside air is supplied to the inside of the data center through the filter (100_1), the air supply duct (71_1) and the air flow panel (60_1).

If the temperature of all hot zone is more than the reference temperature, the main controller (332) operates both the exhaust blower (80_1, 80_2) and the air supply blower (90_1, 90_2) by turning on all magnets (Magnet 1, Magnet 2), thereby supplying the outside air to the inside of the data center simultaneously while exhausting the hot air of all hot zones. At this time, the main controller (332) may detects the temperature of each hot zone in detail by subdividing the reference temperature, that is, using a plurality of temperatures which are different from each other. Hereby, the main controller (332) may independently controls the blowing speed of each of the exhaust blower (80_1, 80_2) and the air supply blower (90_1, 90_2) by individually controlling the each power amount supplied to the exhaust blower (80_1, 80_2) and the air supply blower (90_1, 90_2).

While the exhaust blower (80_1) and the air supply blower (90_1) operate, by continuously checking the temperature of the corresponding hot zone by detector (310), the main controller (332) indentifies whether the temperature of the hot zone is lower than the reference temperature again (step 440).

If the temperature of the hot zone is lower than the reference temperature by exhausting the hot air to the outside and supplying the outside air, the main controller (332) blocks the power supply supplied to the exhaust blower (80_1) and the air supply blower (90_1) by turning off the magnet (Magnet 1).

The operations of the above described steps 410 through 440 are repeatedly preformed until a different manipulation (instruction) by an operator.

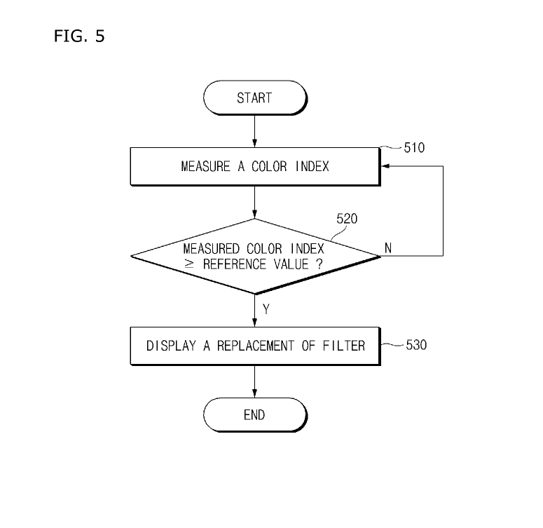

FIG. 5 is a flowchart illustrating a method for managing the replacement of an air supply filter in the air conditioning management method according to an embodiment of the present invention.

A infrared sensor (110_2) periodically irradiates a filter (110_1) with infrared rays, and then detects the reflected light amount, and transmits the results to a micro controller (312). The micro controller (312) processes the sensing signal from a infrared sensor (110_2) and measures a color index for the filter (110_1) (step 510).

The micro controller (312) transmits the sensing information to the main controller (332) of the controller (330).

The main controller (332) determines whether the color index of the sensing information received from micro controller (312) is more than the preset reference value (step 520).

In these comparisons, after several sensing multiple color indexes of the filter (110_1), the average value is can be compared with the reference value.

If the sensed color index is more than the reference value, the main controller (332) displays the message requesting the replacement of the filter on display unit (334) (step 530).

The above described embodiments of the present invention are for the purpose of illustration, it will be understood by those skilled in the art that various modifications, changes, replacements and addition may be made therein with departing from the spirit and scope of the appended claims, and these modifications and changes are said to belong to the scope of the following claims.

### DESCRIPTION OF THE REFERENCE NUMERAL

| | |
|---|---|
| 10: server rack | 20_1, 20_2: pyramid diffuser |
| 30, 30_1, 30_2: exhaust diffuser | 40, 40_1, 40_2: exhaust duct |
| 50: access door | 60: air flow panel |
| 70_1, 70_2: air supply duct | 80_1, 80_2: exhaust blower |
| 90_1, 90_2: air supply blower | 100: filter box |
| 110_1: filter | 110_2: infrared sensor |
| 120_1, 120_2: temperature sensor | 130: control device |
| 310: detector | 312: micro controllers |
| 320: power supply | 322: block switch |
| 330: The controller | 332: main controller |
| 334: the display unit | |

What is claimed is:

1. An air conditioning management apparatus for a data center comprising:
a detector for detecting a temperature of an air exhausted from server racks, detecting the degree of contamination of a filter for purifying an outside air, and outputting a sensing information for it;
a power supply for supplying a operation power to a exhaust blower for exhausting an inside air of the data center to an outside and an air supply blower for supplying the outside air to the data center; and
a controller for controlling operations of the exhaust blower and the air supply blower by controlling the power supply depending on the sensing information, and determining and notifying a replacement time of the filter.

2. An air conditioning management apparatus of claim 1, wherein rear parts of the server racks are arranged to face each other, spacing a distance apart, and forms a hot zone that causes a hot air emitted from the server racks to be collected in the rear part, the detector detects a temperature of the hot zone.

3. An air conditioning management apparatus of claim 2, wherein the detector comprising:
a temperature sensor for detecting the temperature of the hot zone, installed in the hot zone;
an infrared sensor for detecting the degree of contamination of the filter, installed in a filter box in which the outside air flows; and
a micro controller for processing signals sensed by the temperature sensor and the infrared sensor and transmitting the sensing information to the controller.

4. An air conditioning management apparatus of claim 3, wherein the micro controller measures a color index of the filter using a sensing signal from the infrared sensor.

5. An air conditioning management apparatus of claim 4, wherein the controller displays a message notifying a replacement of the filter, if the color index is more than a reference value or equal to the reference value.

6. An air conditioning management apparatus of claim 1, wherein the air supply includes magnets which are connected to the exhaust blower and the air supply blower.

7. An air conditioning management apparatus of claim 6, wherein the air supply further includes a block switch that can manually block the power at the time of the malfunction of the magnets.

8. An air conditioning management apparatus of claim 6, wherein the controller controls whether a operation power is supplied to the exhaust blower and the air supply blower or not, by controlling on or off of the magnets.

9. An air conditioning management apparatus of claim 8, wherein the controller includes a relay for eliminating a noise generated at the time of the on or off operation of the magnets.

10. An air conditioning management apparatus of claim 1, wherein the controller controls a blowing speed of the exhaust blower and the air supply blower by controlling a power amount supplied to the exhaust blower and the air supply blower depending on a detected temperature.

11. An air conditioning management method of an air conditioning management apparatus of data center which rear parts of server racks are arranged to face each other, spacing a distance apart, and a hot zone that causes a hot air emitted from the server racks to be collected in the rear part is formed, the method comprising the steps of:
detecting a temperature of the hot zone and the degree of contamination of a filter for purifying a outside air;
exhausting the air of the hot zone to outside by operating an exhaust blower and supplying the outside air through the filter to the data center by operating an air supply blower; and
outputting a message notifying a replacement of the filter, If the degree of contamination of the filter is more than a reference value or equal to the reference value.

12. An air conditioning management method of claim 11, wherein the step of detecting the degree of contamination of the filter is measuring a color index of the filter.

13. An air conditioning management method of claim 11, wherein the step of exhausting the air of the hot zone to outside and supplying the outside air to the data center controls a blowing speed by controlling a power amount supplied to the exhaust blower and the air supply blower.
